(19) United States
(12) Patent Application Publication
(10) Pub. No.: US 2025/0364228 A1
(43) Pub. Date: Nov. 27, 2025

(54) SUBSTRATE PROCESSING APPARATUS

(71) Applicant: SEMES CO., LTD., Cheonan-si (KR)

(72) Inventors: Ji Hwan LEE, Cheonan-si (KR); Hyun Min LIM, Cheonan-si (KR); Dong Hun KIM, Cheonan-si (KR)

(73) Assignee: SEMES CO., LTD., Cheonan-si (KR)

(21) Appl. No.: 19/213,746

(22) Filed: May 20, 2025

(30) Foreign Application Priority Data
May 22, 2024 (KR) 10-2024-0066766

(51) Int. Cl. H01J 37/32

(52) U.S. Cl. CPC H01J 37/32669; H01J 37/3244; H01J 2237/002; H01J 2237/332

(57) ABSTRACT

Disclosed is a substrate processing apparatus. The substrate processing apparatus includes a chamber including a processing space defined therein, a substrate support unit disposed in the processing space to support a substrate, a gas supply unit configured to supply a gas to the processing space, a showerhead assembly configured to spray the supplied gas into the processing space, and a plasma generation unit configured to convert the gas supplied to the processing space into plasma. The showerhead assembly contains a fluid containing a magnetic component.

### CROSS-REFERENCE TO THE RELATED APPLICATION

The present application claims priority to and the benefit of Patent Application No. 10-2024-0066766, filed on May 22, 2024, in the Korean Intellectual Property Office, the entire disclosure of which is herein incorporated by reference.

### BACKGROUND

### 1. Field

The present disclosure relates to a substrate processing apparatus, and more particularly to a substrate processing apparatus capable of controlling the density of plasma by applying a magnetic field using a fluid containing a magnetic component and an electromagnet.

### 2. Description of the Related Art

In general, a process of manufacturing a semiconductor device includes a deposition process of forming a film on a semiconductor substrate, a chemical/mechanical polishing process of planarizing the film, a photoresist process of forming a photoresist pattern on the film, an etching process of forming a pattern having electrical characteristics on the film using the photoresist pattern, an ion implantation process of implanting specific ions into a predetermined area of the substrate, a cleaning process of removing impurities on the substrate, and an inspection process of inspecting the surface of the substrate on which the film or the pattern is formed.

Among the above processes, the etching process may use plasma. Plasma may be generated under very high temperature, a strong electric field, or a radio frequency (RF) electromagnetic field.

In the case of conventional substrate processing apparatuses using plasma, the density of the plasma in the central area of the substrate is relatively high, and the density of the plasma in the edge area of the substrate is relatively low. Thus, if the density of the plasma is not separately controlled, the substrate is etched obliquely. This leads to process defects and resultant reduction in yield.

Therefore, it is very important to control the density of plasma between the central area and the edge area of the substrate.

### SUMMARY

The present disclosure has been made to solve the above problems, and an aspect of the present disclosure is directed to providing a substrate processing apparatus capable of controlling the density of plasma generated in a processing space in a chamber to be uniform.

The aspects of the present disclosure are not limited to the aspect mentioned above, and other aspects not mentioned herein will be clearly understood by those skilled in the art from the following description.

A substrate processing apparatus according to an embodiment of the present disclosure includes a chamber including a processing space defined therein, a substrate support unit disposed in the processing space to support a substrate, a gas supply unit configured to supply a gas to the processing space, a showerhead assembly configured to spray the supplied gas into the processing space, and a plasma generation unit configured to convert the gas supplied to the processing space into plasma. The showerhead assembly contains a fluid containing a magnetic component.

In one embodiment, the magnetic component may include ferrite.

In one embodiment, the showerhead assembly may include a cooling plate including a refrigerant path formed therein, a gas distribution plate disposed under the cooling plate and including a through-hole formed therein, and a shower plate disposed under the gas distribution plate and including a gas spray hole formed therein.

In one embodiment, the substrate processing apparatus may include a plurality of permanent magnets or a plurality of electromagnets.

A substrate processing apparatus according to another embodiment of the present disclosure includes a chamber including a processing space defined therein, a substrate support unit disposed in the processing space to support a substrate, a gas supply unit configured to supply a gas to the processing space, a showerhead assembly configured to spray the supplied gas into the processing space, a plasma generation unit configured to convert the gas supplied to the processing space into plasma, and a controller configured to control the gas supply unit and the plasma generation unit. The showerhead assembly includes a cooling plate including a refrigerant path formed therein and a plurality of permanent magnets or a plurality of electromagnets disposed so as to face the refrigerant path, and a fluid containing a magnetic component is supplied to the refrigerant path.

In one embodiment, the magnetic component may include ferrite.

In one embodiment, the plurality of permanent magnets or the plurality of electromagnets may be disposed in the cooling plate.

In one embodiment, the showerhead assembly may include an upper plate including a gas inlet hole formed therein, a gas distribution plate including a through-hole formed therein, and a shower plate disposed under the gas distribution plate and including a gas spray hole formed therein.

In one embodiment, the cooling plate may be disposed between the upper plate and the gas distribution plate.

In one embodiment, the plurality of permanent magnets or the plurality of electromagnets may be disposed radially with respect to the center of the cooling plate.

In one embodiment, the cooling plate may include a plurality of gas supply holes formed therein.

In one embodiment, the showerhead assembly may include a plurality of electromagnets disposed so as to face the refrigerant path, and the controller may control a current applied to the plurality of electromagnets to control the density of plasma generated in the processing space.

A substrate processing apparatus according to still another embodiment of the present disclosure includes a chamber including a processing space defined therein, a substrate support unit disposed in the processing space to support a substrate, a gas supply unit configured to supply a gas to the processing space, a showerhead assembly configured to spray the supplied gas into the processing space, a plasma generation unit configured to convert the gas supplied to the processing space into plasma, and a controller configured to control the gas supply unit and the plasma generation unit. The showerhead assembly includes a fluid plate, the fluid plate contains a fluid containing a magnetic component, and a plurality of electromagnets is disposed above the showerhead assembly.

In one embodiment, the magnetic component may include ferrite.

In one embodiment, the fluid plate may include a predetermined space defined therein, and the fluid containing the magnetic component may be disposed in the space.

In one embodiment, the showerhead assembly may include a cooling plate including a refrigerant path formed therein, a gas distribution plate disposed under the cooling plate and including a through-hole formed therein, and a shower plate disposed under the gas distribution plate and including a gas spray hole formed therein.

In one embodiment, the fluid plate may be disposed on the cooling plate.

In one embodiment, the substrate processing apparatus may further include an electromagnet driving unit configured to move positions of the plurality of electromagnets.

In one embodiment, the electromagnet driving unit may include a horizontal driving unit configured to move the plurality of electromagnets in a horizontal direction and a rotation driving unit configured to rotate the plurality of electromagnets.

In one embodiment, the controller may control at least one of positions of the plurality of electromagnets or a current applied to the plurality of electromagnets to control the density of plasma generated in the processing space.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a view showing a substrate processing apparatus according to an embodiment of the present disclosure;

FIG. 2 is an enlarged view of a showerhead assembly of the substrate processing apparatus according to the embodiment of the present disclosure;

FIG. 3 is a top view showing a refrigerant path and electromagnets formed in a cooling plate of the substrate processing apparatus according to the embodiment of the present disclosure;

FIG. 4 is a view showing a substrate processing apparatus according to another embodiment of the present disclosure;

FIG. 5 is an enlarged view of a showerhead assembly of the substrate processing apparatus according to the other embodiment of the present disclosure; and

FIG. 6 is a view showing an electromagnet driving unit of the substrate processing apparatus according to the other embodiment of the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

In the following description of the embodiments of the present disclosure, a detailed description of known functions or configurations incorporated herein will be omitted when it may unnecessarily obscure the subject matter of the present disclosure. Throughout the drawings, parts performing similar functions and operations are denoted by the same reference numerals.

At least some of the terms used in this specification are terms defined taking into consideration the functions obtained in accordance with the present disclosure, and may be changed in accordance with the intention of users or operators or usual practice. Therefore, the definitions of these terms should be determined based on the total content of this specification.

As used herein, singular forms may include plural forms, unless the context clearly indicates otherwise. Additionally, the term “comprise”, “include”, or “have” described herein should be interpreted not to exclude other elements but to further include such other elements unless mentioned otherwise.

In the drawings, the sizes or shapes of elements and thicknesses of lines may be exaggerated for clarity and convenience of description.

Hereinafter, embodiments of the present disclosure will be described in detail with reference to the accompanying drawings, and the same or similar elements are denoted by the same reference numerals even though they are depicted in different drawings, and redundant descriptions thereof will be omitted.

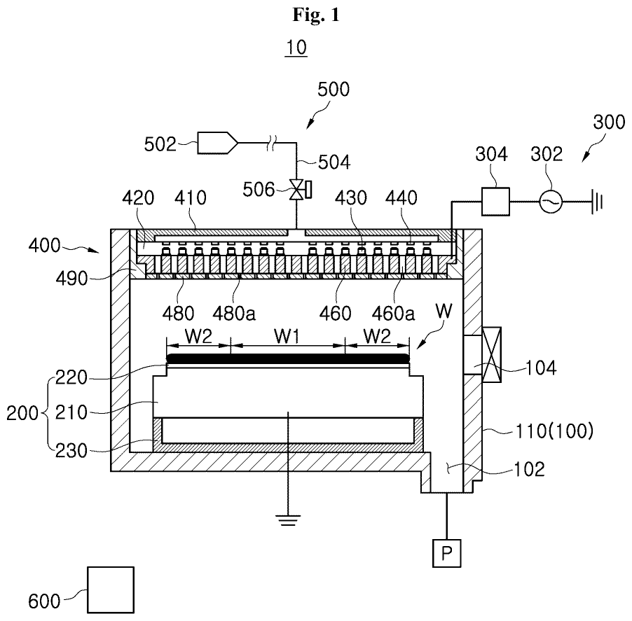

FIG. 1 is a view showing a substrate processing apparatus according to an embodiment of the present disclosure.

Referring to FIG. 1, the substrate processing apparatus 10 may include a chamber 100, a substrate support unit 200, a plasma generation unit 300, a showerhead assembly 400, a gas supply unit 500, and a controller 600.

The chamber 100 may have a processing space defined therein so as to allow a plasma process to be performed therein, and may include a body 110. The body 110 may have an open upper surface and may have an inner space defined therein. In an example, the body 110 may have a cylindrical shape having an open upper surface and having an inner space defined therein. The open upper surface of the body 110 may be sealed by the showerhead assembly 400, which will be described later.

The chamber 100 may include an exhaust port 102 formed in a lower side thereof, and the exhaust port 102 may be connected to an exhaust line on which a pump P is mounted. The exhaust port 102 may discharge reaction by-products generated during the plasma process and gas remaining in the chamber 100 to the outside of the chamber 100 through the exhaust line. In this case, pressure in the inner space in the chamber 100 may be reduced to a predetermined pressure.

The chamber 100 may include an opening 104 formed in the sidewall thereof. The opening 104 may function as a passage through which a substrate W is introduced into and discharged from the chamber 100. The opening 104 may be configured to be opened and closed by a door assembly.

The substrate support unit 200 may be disposed in a lower area in the chamber 100. The substrate support unit 200 may support the substrate W using electrostatic force. However, this embodiment is not limited thereto. The substrate W may be supported in various ways, such as mechanical clamping or vacuum support.

The substrate support unit 200 may include a support body 210 and an electrostatic chuck 220 disposed on the upper surface of the support body 210. The electrostatic chuck 220 may be configured to electrostatically attract and hold the substrate W, and may include a ceramic layer provided with an electrode.

According to an embodiment of the present disclosure, although not shown, the substrate support unit 200 may be provided therein with a heating member and a cooling member to maintain the substrate W at a process temperature. The heating member may be a heating coil, and the cooling member may be provided as a cooling line through which refrigerant flows.

A support member 230 may be provided under the support body 210 in order to support the support body 210 and the electrostatic chuck 220. The support member 230 may be formed in a cylindrical shape having a predetermined height, and may have a space defined therein.

The plasma generation unit 300 may generate plasma in the processing space in the chamber 100. Plasma may be generated in an area above the substrate support unit 200 in the chamber 100. According to an embodiment of the present disclosure, the plasma generation unit 300 may generate plasma in the processing space in the chamber 100 using a capacitively coupled plasma (CCP) source.

However, this embodiment is not limited thereto. The plasma generation unit 300 may also generate plasma in the processing space in the chamber 100 using another type of plasma source, such as an inductively coupled plasma (ICP) source or microwaves.

The plasma generation unit 300 may include a high-frequency power supply 302 and a matching device 304. The high-frequency power supply 302 may supply high-frequency power to any one of an upper electrode and a lower electrode in order to generate a potential difference between the upper electrode and the lower electrode. Here, the upper electrode may be the showerhead assembly 400, and the lower electrode may be the substrate support unit 200. The high-frequency power supply 302 may be connected to the upper electrode, and the lower electrode may be grounded.

The showerhead assembly 400 may be formed in the chamber 100 so as to face the electrostatic chuck 220 vertically. The showerhead assembly 400 may allow gas supplied by the gas supply unit 500 to be uniformly supplied to the processing space.

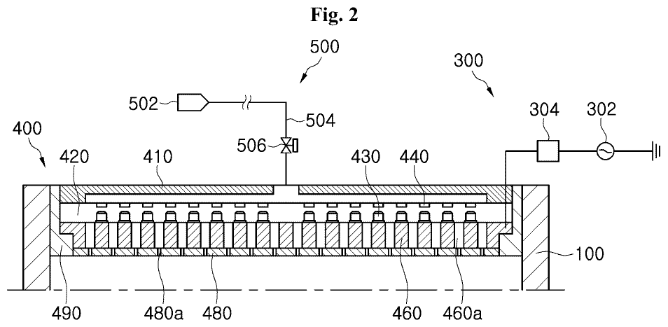

FIG. 2 is an enlarged view of the showerhead assembly of the substrate processing apparatus according to the embodiment of the present disclosure.

Referring to FIG. 2, the showerhead assembly 400 according to the embodiment of the present disclosure may include an upper plate 410, a cooling plate 420, a gas distribution plate 460, a shower plate 480, and an insulating ring 490.

The upper plate 410 may be mounted so as to cover the open upper surface of the chamber 100. The upper plate 410 may include a gas inlet hole formed therein so as to supply gas supplied from the gas supply unit 500 to be described later to the cooling plate 420, the gas distribution plate 460, and the shower plate 480. In addition, the upper plate 410 may be formed to have a predetermined space defined therein.

The cooling plate 420 may be disposed under the upper plate 410 so as to be in close contact with the lower surface of the upper plate 410. The cooling plate 420 may have a circular plate shape. Although not shown in the drawings, a plurality of gas supply holes may be formed in the cooling plate 420.

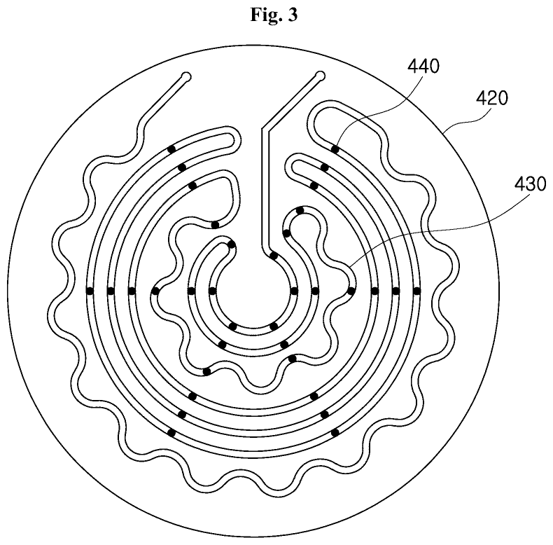

FIG. 3 is a top view showing a refrigerant path and electromagnets formed in the cooling plate of the substrate processing apparatus according to the embodiment of the present disclosure.

Referring to FIGS. 2 and 3 together, a refrigerant path 430 and a plurality of electromagnets 440 may be formed in the cooling plate 420.

The refrigerant path 430 may be formed in the cooling plate 420 to regulate the temperature of the showerhead assembly 400. According to the embodiment of the present disclosure, the refrigerant path 430 may be formed in the lower surface of the cooling plate 420, and a magnetic fluid may flow through the refrigerant path 430.

The magnetic fluid of the present disclosure may be manufactured by dispersing a magnetic component in a fluid. In order to manufacture the magnetic fluid, when a magnetic component is added to a fluid in a dispersed manner, a surfactant may be added in order to lower interfacial energy between the fluid and the magnetic component so that the two substances are effectively mixed with each other.

According to the embodiment of the present disclosure, H₂O, kerosene, mineral oil, silicon oil, or the like may be used as the fluid, and oleic acid, silica, chitosan, acrylic acid, or the like may be used as the surfactant. The magnetic component may be ferrite. However, this embodiment is not limited thereto. For example, the magnetic component may be a combination of ferrite and Co, Ni, Zn, or Mg, Fe—Pt, Ni—Fe, Fe—Co, CoFe₂O₄, MnFe₂O₄, NiFe₂O₄, Mn_{0.5}Zn_{0.5}Fe₂O₄, LizFe₂O₄, ZnFe₂O₄, or the like.

The plurality of electromagnets 440 may be formed in the cooling plate 420 of the showerhead assembly 400. According to the embodiment of the present disclosure, the plurality of electromagnets 440 may be formed in the upper surface of the cooling plate 420. When viewed in cross-section, the plurality of electromagnets 440 may be provided to face the refrigerant path 430. In addition, the plurality of electromagnets 440 may be disposed radially with respect to the center of the cooling plate 420.

The electromagnets 440 according to the embodiment of the present disclosure may be provided so that the direction and magnitude of the magnetic field is adjusted. A power supply (not shown) may be connected to each of the electromagnets 440. When the power supply (not shown) supplies current and the current flows through each of the electromagnets 440, each of the electromagnets 440 may generate an individual magnetic field. The individual magnetic field generated by each of the electromagnets 440 may be amplified by the fluid containing the magnetic component that flows through the refrigerant path 430. Accordingly, the density of the plasma generated in the chamber 100 may also be amplified. Although the embodiment of the present disclosure has been described as using the electromagnets, permanent magnets may be used. A gap between the electromagnets 440 and the refrigerant path 430 may also be adjusted.

Referring again to FIG. 2, the gas distribution plate 460 may be disposed under the cooling plate 420 so as to be in close contact with the lower surface of the cooling plate 420. The gas distribution plate 460 may have a circular plate shape and may include a plurality of through-holes 460a formed therein. The gas distribution plate 460 may include a metallic material. The gas distribution plate 460 may function as an upper electrode.

The shower plate 480 may be disposed under the gas distribution plate 460. The shower plate 480 may have a circular plate shape. The shower plate 480 may include a plurality of gas spray holes 480a formed therein so as to be connected to the through-holes 460a formed in the gas distribution plate 460.

The insulating ring 490 may be disposed so as to surround the peripheries of the upper plate 410, the cooling plate 420, the gas distribution plate 460, and the shower plate 480. The insulating ring 490 may be formed in a generally annular ring shape. The insulating ring 490 may be made of a non-metallic material.

As described above, a fluid containing a magnetic component may be supplied to the refrigerant path in the cooling plate, and a plurality of electromagnets may be provided so as to face the refrigerant path, whereby the density of plasma generated in the chamber may be controlled. In detail, when current is supplied to the electromagnets, the intensity of magnetic field the generated by the electromagnets may increase due to the fluid containing the magnetic component. Due to increase in the intensity of the magnetic field, the density of the plasma generated in the processing space in the chamber may also increase. The density of the plasma in the chamber may be controlled by controlling on/off and the intensity of current supplied to the electromagnets. Accordingly, the density of the plasma supplied to a central area W1 of the substrate W and the density of the plasma supplied to an edge area W2 of the substrate W may become substantially identical or similar to each other, whereby the entire surface of the substrate W may be more uniformly etched, and thus yield may be improved. In addition, since the fluid containing a magnetic component is supplied to the refrigerant path, it may be possible to reduce the size of the electromagnets and thus to reduce the size of the substrate processing apparatus.

Referring again to FIG. 1, the gas supply unit 500 may supply gas required for the process to the chamber 100. The gas supply unit 500 may include a gas source 502, a gas supply line 504, and a gas injection nozzle (not shown). The gas supply line 504 may connect the gas source 502 to the gas injection nozzle (not shown). The gas supply line 504 may supply gas stored in the gas source 502 to the gas injection nozzle. A valve 506 may be mounted on the gas supply line 504 in order to open and close the passage of the gas supply line 504 or to regulate the flow rate of a fluid flowing through the passage.

Although one gas source 502, one gas supply line 504, and one gas supply valve 506 are illustrated in FIG. 1, the gas supply unit of the present disclosure may include a plurality of gas sources to supply a plurality of gases to the chamber 100, a plurality of gas supply lines, and a plurality of gas supply valves to independently control supply of the respective gases.

The controller 600 may comprehensively control the operation of the substrate processing apparatus 10 configured as described above. The controller 600 may be, for example, a computer, and may include a central processing unit (CPU), random access memory (RAM), read only memory (ROM), and an auxiliary storage device. The CPU may operate on the basis of a program stored in the ROM or the auxiliary storage device or process conditions to control the overall operation of the apparatus 10. In addition, a computer-readable program necessary for control may be stored in a storage medium. The storage medium may include, for example, a floppy disk, a compact disc (CD), a CD-ROM, a hard disk, a flash memory, a DVD, or the like. The controller 600 may be provided inside or outside the substrate processing apparatus 10. In the case in which the controller 600 is provided outside the substrate processing apparatus 10, the controller 600 may control the substrate processing apparatus 10 using a wired or wireless communication system.

In order to implement the process, the controller 600 according to the embodiment of the present disclosure may perform control such that gas is supplied to the processing space in the chamber 100 and the supplied gas is converted into plasma by the plasma generation unit 300. In addition, the controller 600 may control the intensity and on/off of current supplied to the plurality of electromagnets 440 formed in the cooling plate 420 of the showerhead assembly 400, thereby controlling the density of the plasma generated in the chamber 100.

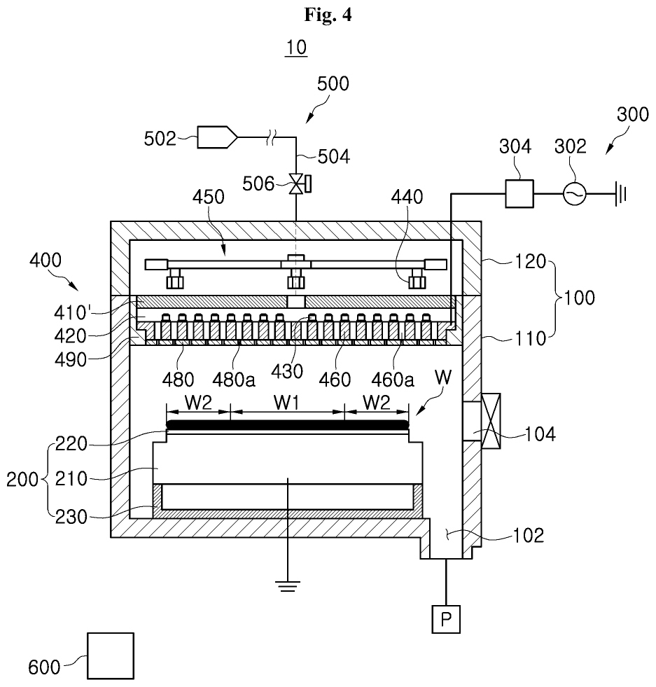

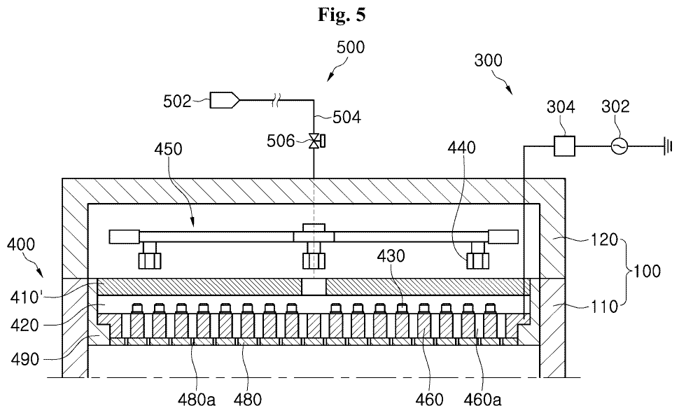

FIG. 4 is a view showing a substrate processing apparatus according to another embodiment of the present disclosure, and FIG. 5 is an enlarged view of a showerhead assembly of the substrate processing apparatus according to the other embodiment of the present disclosure.

Unlike the substrate processing apparatus 10 shown in FIG. 1, the substrate processing apparatus shown in FIG. 4 may be configured such that a plurality of electromagnets 440 is formed above a showerhead assembly 400, rather than being formed inside the showerhead assembly 400.

Referring to FIGS. 4 and 5, the substrate processing apparatus 10 may include a plurality of electromagnets 440 formed above the showerhead assembly 400.

A chamber 100 may include a body 110 and a cover 120. The body 110 may have an open upper surface and may have an inner space defined therein. In an example, the body 110 may have a cylindrical shape having an open upper surface and having an inner space defined therein. The cover 120 may be provided on the upper end of the body 110. The cover 120 may seal the open upper surface of the body 110. In an example, the cover 120 may have a cylindrical shape having an open lower surface. The body 110 and the cover 120 may be assembled to each other to form the chamber 100.

The showerhead assembly 400 according to the other embodiment of the present disclosure may include a fluid plate 410′, a cooling plate 420, a gas distribution plate 460, and a shower plate 480.

The fluid plate 410′ may be mounted so as to cover the open upper surface of the body 110 of the chamber 100. The fluid plate 410′ may include a gas inlet hole formed therein so as to supply gas supplied from a gas supply unit 500 to be described later to the cooling plate 420, the gas distribution plate 460, and the shower plate 480.

The fluid plate 410′ according to the other embodiment may have defined therein a space having a predetermined size, and a magnetic fluid may be provided in the space in the fluid plate 410′. The magnetic fluid of the present disclosure may be manufactured by dispersing a magnetic component in a fluid. In order to manufacture the magnetic fluid, when a magnetic component is added to a fluid in a dispersed manner, a surfactant may be added in order to lower interfacial energy between the fluid and the magnetic component so that the two substances are effectively mixed with each other.

According to the other embodiment of the present disclosure, H₂O, kerosene, mineral oil, silicon oil, or the like may be used as the fluid, and oleic acid, silica, chitosan, acrylic acid, or the like may be used as the surfactant. The magnetic component may be ferrite. However, this embodiment is not limited thereto. For example, the magnetic component may be a combination of ferrite and Co, Ni, Zn, or Mg, Fe—Pt, Ni—Fe, Fe—Co, CoFe₂O₄, MnFe₂O₄, NiFe₂O₄, Mn_{0.5}Zn_{0.5}Fe₂O₄, LizFe₂O₄, ZnFe₂O₄, or the like.

The cooling plate 420 may be disposed under the fluid plate 410′ so as to be in close contact with the lower surface of the fluid plate 410′. The cooling plate 420 may have a circular plate shape. Although not shown in the drawings, a plurality of gas supply holes may be formed in the cooling plate 420. In addition, the cooling plate 420 may include a refrigerant path 430 formed therein so as to regulate the temperature of the showerhead assembly 400. In the other embodiment of the present disclosure, a cooling fluid not containing a magnetic component flow may through the refrigerant path 430.

The gas distribution plate 460 may be disposed under the cooling plate 420 so as to be in close contact with the lower surface of the cooling plate 420. The gas distribution plate 460 may have a circular plate shape and may include a plurality of through-holes 460a formed therein. The gas distribution plate 460 may include a metallic material. The gas distribution plate 460 may function as an upper electrode.

The shower plate 480 may be disposed under the gas distribution plate 460. The shower plate 480 may have a circular plate shape. The shower plate 480 may include a plurality of gas spray holes 480a formed therein so as to be connected to the through-holes 460a formed in the gas distribution plate 460.

The insulating ring 490 may be disposed so as to surround the peripheries of the fluid plate 410′, the cooling plate 420, the gas distribution plate 460, and the shower plate 480. The insulating ring 490 may be formed in a generally annular ring shape. The insulating ring 490 may be made of a non-metallic material.

A plurality of electromagnets 440 may be provided above the showerhead assembly 400. According to the other embodiment of the present disclosure, four electromagnets 440 may be provided. The four electromagnets 440 may be disposed along a circular path at regular intervals with respect to the center of the showerhead assembly 400. In addition, the substrate processing apparatus 10 according to the other embodiment of the present disclosure may further include an electromagnet driving unit 450 to drive the electromagnets 440.

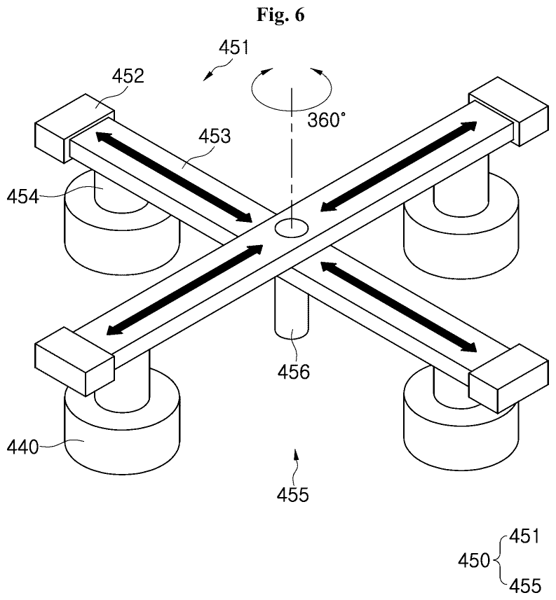

FIG. 6 is a view showing the electromagnet driving unit of the substrate processing apparatus according to the other embodiment of the present disclosure.

Referring to FIG. 6, the electromagnet driving unit 450 may include a horizontal driving unit 451 to move the plurality of electromagnets 440 in a horizontal direction and a rotation driving unit 455 to rotate the plurality of electromagnets 440.

The horizontal driving unit 451 may move each of the plurality of electromagnets 440 in the horizontal direction. The horizontal driving unit 451 may include a plurality of horizontal driving mechanisms 452, a plurality of guide rails 453, and a plurality of support rods 454. A plate (not shown) may be mounted to each of the guide rails 453 so as to be movable in the horizontal direction along each of the guide rails 453. One end of each of the support rods 454 may be coupled to a corresponding one of the electromagnets 440, and the other end of each of the support rods 454 may be coupled to the plate (not shown) mounted to a corresponding one of the guide rails 453. The lower surfaces of the plurality of electromagnets 440 coupled to the support rods 454 may be disposed at the same height. However, this embodiment is not limited thereto. The horizontal driving mechanisms 452 may move the electromagnets 440 in the horizontal direction along the guide rails 453. The horizontal driving mechanisms 452 may be motors.

The rotation driving unit 455 may rotate the plurality of electromagnets 440 at the same time. The rotation driving unit 455 may rotate the plurality of electromagnets 440 in the clockwise or counterclockwise direction. The rotation driving unit 455 may include a rotation shaft 456 and a rotation driving mechanism (not shown) coupled to the rotation shaft 456 in order to rotate the electromagnets 440. The rotation driving mechanism (not shown) may be a motor.

As described above, because the fluid plate includes a magnetic component and a plurality of electromagnets and an electromagnet driving unit are provided above the showerhead assembly, the density of plasma generated in the chamber may be controlled. In detail, when current is supplied to the electromagnets, the intensity of a magnetic field generated by the electromagnets may increase due to the fluid containing a magnetic component in the fluid plate. Due to increase in the intensity of the magnetic field, the density of the plasma generated in the processing space in the chamber may also increase. The density of the plasma in the chamber may be controlled to be uniform by controlling on/off and the intensity of current supplied to the electromagnets and the positions of the electromagnets. Accordingly, the density of the plasma supplied to the central area W1 of the substrate W and the density of the plasma supplied to the edge area W2 of the substrate W may become substantially identical or similar to each other, whereby the entire surface of the substrate W may be more uniformly etched, and thus yield may be improved. In addition, since the fluid containing a magnetic component is supplied to the fluid plate, it may be possible to reduce the size of the electromagnets and thus to reduce the size of the substrate processing apparatus.

In addition, the above embodiments may be combined with each other. For example, in the case in which the refrigerant path containing a magnetic fluid is formed in the cooling plate, electromagnets and an electromagnet driving unit may be provided above the showerhead assembly. In addition, in the case in which the fluid plate contains a magnetic fluid, electromagnets may be provided in the cooling plate of the showerhead assembly.

As is apparent from the above description, according to the present disclosure, it may be possible to control a magnetic field generated in a chamber using a fluid containing a magnetic component and permanent magnets or electromagnets.

The uniformity of the density of plasma generated in the chamber may be improved by controlling the magnetic field, whereby the entire surface of a substrate may be more uniformly etched.

In addition, it may be possible to reduce the size of the permanent magnets or electromagnets using the fluid containing a magnetic component.

The effects achievable through the present disclosure are not limited to the above-mentioned effects, and other effects not mentioned herein will be clearly understood by those skilled in the art from the above description.

It will be apparent to those skilled in the art that various changes in form and details may be made without departing from the essential characteristics of the disclosure set forth herein. Accordingly, the above detailed description is not intended to be construed to limit the disclosure in all aspects and to be considered by way of example. The scope of the disclosure should be determined by reasonable interpretation of the appended claims and all equivalent modifications made without departing from the disclosure should be included in the following claims.

What is claimed is:

1. A substrate processing apparatus comprising:
a chamber comprising a processing space defined therein;
a substrate support unit disposed in the processing space, the substrate support unit being configured to support a substrate;
a gas supply unit configured to supply a gas to the processing space;
a showerhead assembly configured to spray the supplied gas into the processing space; and
a plasma generation unit configured to convert the gas supplied to the processing space into plasma,
wherein the showerhead assembly contains a fluid containing a magnetic component.

2. The substrate processing apparatus as claimed in claim 1, wherein the magnetic component comprises ferrite.

3. The substrate processing apparatus as claimed in claim 1, wherein the showerhead assembly comprises:
a cooling plate comprising a refrigerant path formed therein;
a gas distribution plate disposed under the cooling plate, the gas distribution plate comprising a through-hole formed therein; and
a shower plate disposed under the gas distribution plate, the shower plate comprising a gas spray hole formed therein.

4. The substrate processing apparatus as claimed in claim 1, comprising a plurality of permanent magnets or a plurality of electromagnets.

5. A substrate processing apparatus comprising:
a chamber comprising a processing space defined therein;
a substrate support unit disposed in the processing space, the substrate support unit being configured to support a substrate;
a gas supply unit configured to supply a gas to the processing space;
a showerhead assembly configured to spray the supplied gas into the processing space;
a plasma generation unit configured to convert the gas supplied to the processing space into plasma; and
a controller configured to control the gas supply unit and the plasma generation unit,
wherein the showerhead assembly comprises:
a cooling plate comprising a refrigerant path formed therein; and
a plurality of permanent magnets or a plurality of electromagnets disposed so as to face the refrigerant path, and
wherein a fluid containing a magnetic component is supplied to the refrigerant path.

6. The substrate processing apparatus as claimed in claim 5, wherein the magnetic component comprises ferrite.

7. The substrate processing apparatus as claimed in claim 5, wherein the plurality of permanent magnets or the plurality of electromagnets are disposed in the cooling plate.

8. The substrate processing apparatus as claimed in claim 5, wherein the showerhead assembly comprises:
upper plate comprising a gas inlet hole formed therein;
a gas distribution plate comprising a through-hole formed therein; and
a shower plate disposed under the gas distribution plate, the shower plate comprising a gas spray hole formed therein.

9. The substrate processing apparatus as claimed in claim 8, wherein the cooling plate is disposed between the upper plate and the gas distribution plate.

10. The substrate processing apparatus as claimed in claim 7, wherein the plurality of permanent magnets or the plurality of electromagnets is disposed radially with respect to a center of the cooling plate.

11. The substrate processing apparatus as claimed in claim 7, wherein the cooling plate comprises a plurality of gas supply holes formed therein.

12. The substrate processing apparatus as claimed in claim 5, wherein the showerhead assembly comprises a plurality of electromagnets disposed so as to face the refrigerant path, and
wherein the controller controls a current applied to the plurality of electromagnets to control a density of the plasma generated in the processing space.

13. A substrate processing apparatus comprising:
a chamber comprising a processing space defined therein;
a substrate support unit disposed in the processing space, the substrate support unit being configured to support a substrate;
a gas supply unit configured to supply a gas to the processing space;
a showerhead assembly configured to spray the supplied gas into the processing space;
a plasma generation unit configured to convert the gas supplied to the processing space into plasma; and
a controller configured to control the gas supply unit and the plasma generation unit,
wherein the showerhead assembly comprises a fluid plate,
wherein the fluid plate contains a fluid containing a magnetic component, and
wherein a plurality of electromagnets is disposed above the showerhead assembly.

14. The substrate processing apparatus as claimed in claim 13, wherein the magnetic component comprises ferrite.

15. The substrate processing apparatus as claimed in claim 13, wherein the fluid plate comprises a predetermined space defined therein, and
wherein the fluid containing the magnetic component is disposed in the predetermined space of the fluid plate.

16. The substrate processing apparatus as claimed in claim 14, wherein the showerhead assembly comprises:
a cooling plate comprising a refrigerant path formed therein;
a gas distribution plate disposed under the cooling plate, the gas distribution plate comprising a through-hole formed therein; and
a shower plate disposed under the gas distribution plate, the shower plate comprising a gas spray hole formed therein.

17. The substrate processing apparatus as claimed in claim 16, wherein the fluid plate is disposed on the cooling plate.

18. The substrate processing apparatus as claimed in claim 14, further comprising an electromagnet driving unit configured to move positions of the plurality of electromagnets.

19. The substrate processing apparatus as claimed in claim 18, wherein the electromagnet driving unit comprises:
a horizontal driving unit configured to move the plurality of electromagnets in a horizontal direction; and
a rotation driving unit configured to rotate the plurality of electromagnets.

20. The substrate processing apparatus as claimed in claim 18, wherein the controller controls at least one of the positions of the plurality of electromagnets or a current applied to the plurality of electromagnets to control a density of the plasma generated in the processing space.
